(19) United States
(12) Patent Application Publication
(10) Pub. No.: US 2007/0212800 A1
(43) Pub. Date: Sep. 13, 2007

(54) Methods for detecting charge effects during semiconductor processing

(75) Inventors: Chao-I Wu, Tainan (TW); Ming Hsiu Lee, Hsinchu (TW); Ming-Chang Kuo, Changhua (TW)

Correspondence Address: BAKER & MCKENZIE LLP;PATENT DEPARTMENT, 2001 ROSS AVENUE, SUITE 2300, DALLAS, TX, 75201, US

(73) Assignee: Macronix International Co., Ltd.

(21) Appl. No.: 11/370,362

(22) Filed: Mar. 8, 2006

(51) Int. Cl. H01L 21/66

(52) U.S. Cl. 438/14

(57) ABSTRACT

A semiconductor process test structure comprises a gate electrode, a charge-trapping layer, and a diffusion region. The test structure is a capacitor-like structure in which the charge-trapping layer will trap charges during various processing steps. A charge pump current can be used to detect the charging effect during various processing steps.

### BACKGROUND

1. Field of the Invention

This invention relates generally to testing and diagnostics of line processes used for the manufacture of integrated circuit devices, and more particularly to methods for measurement and monitoring the charging effect on a semiconductor device.

2. Background of the Invention

The manufacture of large-scale integrated circuits involves hundreds of discrete processing steps. These steps are typically divided into two sub-processes. The first of these sub-processes is often referred to as the front-end of line (FEOL) sub-process during which the semiconductor devices are formed within a silicon wafer. The second of the sub-processes is often termed the back-end of line (BEOL) sub-process during which various metal interconnecting layers and contacts are formed on top of the semiconductor devices formed during the FEOL sub-process.

Many of the processing steps comprising the FEOL and BEOL sub-processes involve depositing layers of material, patterning the layers by photolithographic techniques, and then etching away unwanted portions of the deposited material. The deposited materials primarily consist of insulators and metal alloys. In some instances the pattern layer serves as temporary protective mass, while on others they are functional components of the integrated circuit chips being formed.

Radio frequency (RF) plasmas are often used in many of the processing steps, especially in the processing steps comprising the BEOL sub-process. For example, RF plasmas are used in Reactive Ion Etching (RIE), which is used to etch the layers of material as described above. RIE provides the etching anisotropy required to achieve the requisite high degree of pattern definition and precision and the requisite precision dimensional control. In RIE, gaseous chemical etching is assisted by unidirectional ion bombardment provided by an RF plasma. Photo-resist layers, used in the photolithographic patterning described above, are also frequently removed using plasma ashing.

Unfortunately, the numerous exposures to the RF plasmas, and other forms of ionic radiation, results in radiation damage and the accumulation of charge on exposed conductive components, which leads to damaging current flows and trapped charges affecting the semiconductor devices and integrated circuit chips being formed. The surfaces of the patterned semiconductor wafer present multiple areas of conductors and insulators to the RF plasmas. The multiple areas of conductors and insulators produce local non-uniformities in the plasma currents, which can result in charge build up on the electrically floating conductor surfaces. This charge build up can produce the damaging current flows and can affect the threshold voltages for semiconductor structures formed on the silicon wafer.

The semiconductor devices often comprise some form of field effect transistor comprising a gate, drain, and source regions. The mechanism of current flow through the oxide layer forming the gate is primarily the result of Fowler-Nordheim (FN) tunneling. FN tunneling occurs at fields in excess of 10 MV/cm. Charge build up on the gate electrode resulting in a gate electro potential of only 10 volts is therefore sufficient to induce FN tunneling through an oxide layer of 100 A. Such potentials are easily achieved in conventional plasma reactors used to generate RF plasmas and semiconductor processing. Excessive FN tunneling currents eventually lead to positively charged interface traps in the oxide layer forming the gate, which can lead to subsequent dielectric breakdown.

As the semiconductor wafer is exposed to successive processing steps, the damage or potential damage is increased. As a result, efforts are made to assess the damage produced in the various semiconductor processing steps. For example, one common way to test for the level of damage is to produce test wafers or test chips comprising structures designed to measure, or allow measurement of, the damage produced by various processing steps.

Test structures are typically formed within a specifically designated test site on a semiconductor wafer being processed. Alternatively, entire wafers can be devoted to providing a plurality of test structures for process monitoring. Thus, the test structures are run through the process which results in charge build up that can be then measured. A common method for measuring the charging status is to use Capacitance-Voltage (CV) techniques. Such techniques, however, are often unsatisfactory for the semiconductor industry because of their low sensitivity, high test chip cost, or long delay time associated with the production of data related to the testing.

For example, the CV method can only be used for processes with uniform charging effect. In other words, for processes that result in charge accumulating at the edge of the gate structure, CV methods will suffer from insufficient capacitance change produced by the trapped charges. The insufficient capacitance change will render conventional CV methods insufficient for monitoring the charging status.

### SUMMARY

A semiconductor process test structure comprises a gate electrode, a charge-trapping layer, and a diffusion region. The test structure is a capacitor-like structure in which the charge-trapping layer will trap charges during various processing steps.

In one aspect, charge pump current can be used to detect the charging effect during various processing steps.

These and other features, aspects, and embodiments of the invention are described below in the section entitled “Detailed Description.”

### BRIEF DESCRIPTION OF THE DRAWINGS

Features, aspects, and embodiments of the inventions are described in conjunction with the attached drawings, in which:

FIG. 1 is a diagram illustrating an example test device structure for detecting charge effect during semiconductor wafer manufacturing process steps in accordance with one embodiment;

FIG. 2 is a diagram illustrating a top view of the test device structure of FIG. 1;

FIG. 3A is a diagram illustrating a simplified representation of the test device structure of FIG. 1;

FIG. 3B is a diagram illustrating bias voltage pulses that can be applied to the gate of the test device structure of FIG. 1;

FIG. 3C is a diagram illustrating the charge pumping current produced in the test device of FIG. 1 as a result of the bias voltage pulses of FIG. 3B;

FIG. 4 is a graph illustrating a shift in the charge pump current for a certain test device structure; and

FIG. 5 is a diagram illustrating a shift in the charge pumping current for another example test device structure.

### DETAILED DESCRIPTION OF THE PREFERRED EMBODIMENTS

The systems and methods described herein are directed to methods for using simple capacitor-like test structures to detect the charging effect during semiconductor processing. The structures can be used to reduce test wafer costs and shorten the delay time for producing test data that can be used to modify the semiconductor processes at issue in order to reduce damage resulting from charge accumulation during processing steps.

The charging effect is a result of the trapped charge produced by the various processing steps described above. The charging effect can be an important issue, especially in memory devices. This is because the charging effect can affect the threshold voltage (Vt) distribution for the memory device, which can affect the operation window and degrade reliability.

In the systems and methods described below a simple test device structure comprising a selected pattern can be used to produce a charge pumping current (ICP). The ICP can then be used to detect the charging effect. The test device structures in the methods described below can be used to detect both processing charging effects and ultraviolet (UV)-induced charging effects.

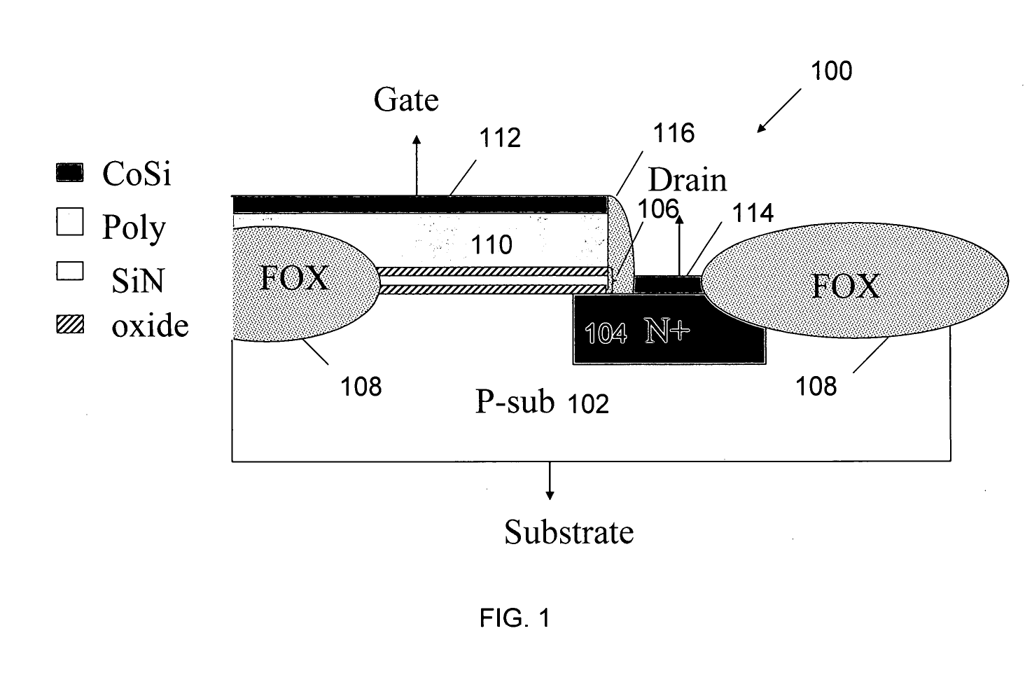

FIG. 1 is a diagram illustrating an example test device structure 100 configured in accordance with one embodiment described herein. As can be seen, test device structure 100 comprises a silicon substrate 102 with a drain region 104 implanted therein. In the embodiment of FIG. 1, silicon substrate 102 is p-type silicon substrate, and drain 104 is an N+ region implanted in the p-type silicon substrate. It will be clear however that in other embodiments the substrate can be an n-type silicon substrate with a P+ drain region implanted therein.

A gate structure can then be formed on top of substrate 102 extending over a portion of drain region 104. The gate structure can comprise a trapping layer 106 with a polysilicon layer 110 formed thereon. Both the gate and drain can have metal, or metal silicide layers formed thereon. In the example of FIG. 1, both the gate and drain regions have silicide layers comprising cobalt and silicon (CoSi) formed thereon.

Device 100 can also comprise an oxide spacer 116 and field oxide layer 108.

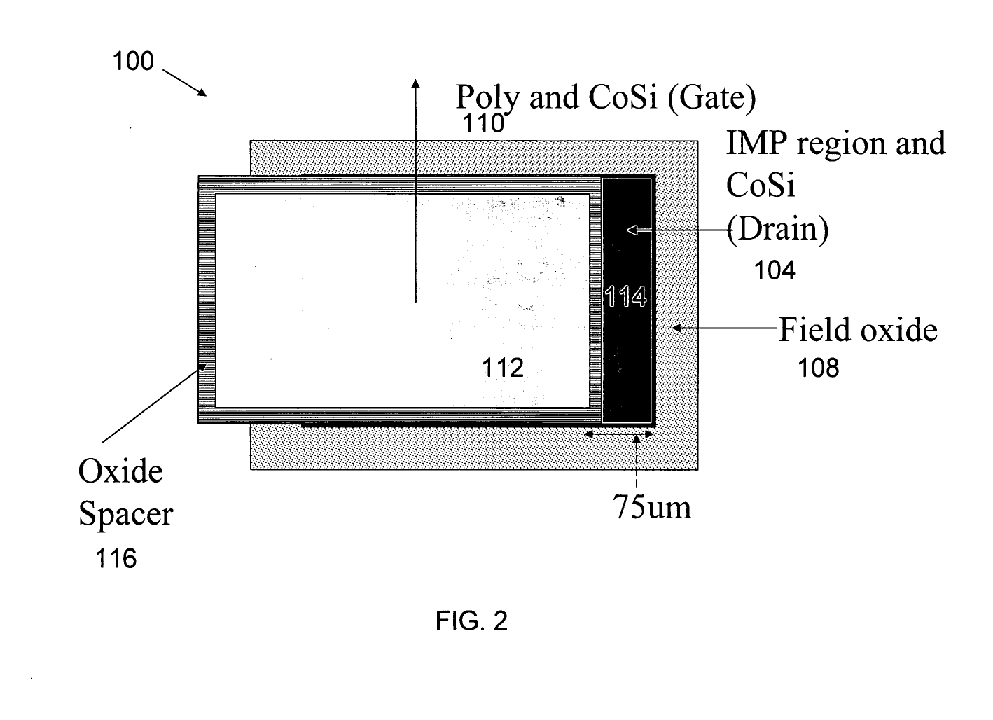

FIG. 2 is a diagram illustrating a top view of test device structure 100. As can be seen, drain region 104 can extend out from under the gate structure. In the example of FIG. 2, drain region 104 extends 75 μm from under the gate structure. The dimensions of test device structure 100, including such dimensions as how far drain region 104 extends out from under the gate structure will vary depending on the requirements for a particular implementation.

As will be discussed in more detail below, test device structure 100 is just one example of a simple test device structure that can be used in accordance with the methods described herein. It will be apparent that many other test device structures and test device structure patterns can be used in accordance with the methods described herein. Accordingly, test device structure 100 should not be seen as limiting the methods and apparatus described herein to any particular structure or pattern.

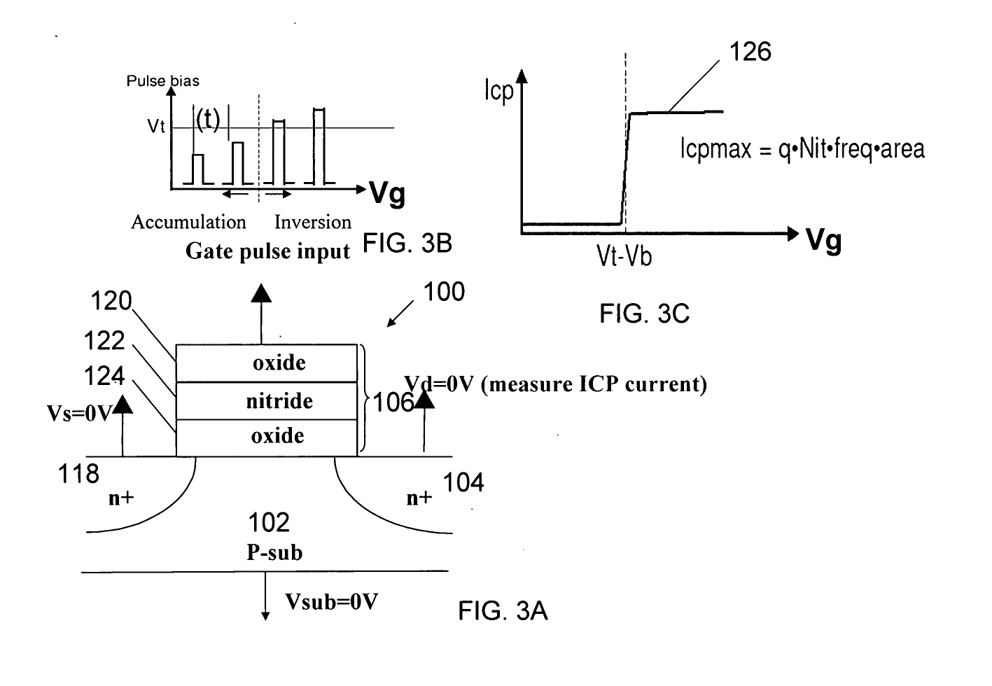

FIG. 3A is a simplified diagram of test device structure 100. In FIG. 3A, a source region 118 implanted in substrate 102 is also illustrated. Further, charge trapping layer 106 in the example of FIG. 3A comprises a nitride layer 122, such as a silicon nitride layer, sandwiched between two oxide layers 120 and 124. It will be understood, that charge can be trapped in nitride layer 122 of trapping layer 106. It will be further understood that other trapping layers, and trapping layer configurations can be used depending on the embodiment.

Thus, it will be clear, that test device structure 100 comprises a memory structure in which charge can be stored in trapping layer 106. During semiconductor manufacturing, however, charge can become trapped in trapping layer 106 creating the charging effect referred to above. A charge pumping current (ICP) can be used to determine the extent of the charging effect. This is because the ICP curve will be affected by the charge trapped in trapping layer 106. Further, the density of the trapped charge can also affect the ICP curve.

Accordingly, changes in the ICP curve for test device structure 100 can be used to monitor the charging effect. Advantageously, simple test device structures comprising simple to complex patters can be used to produce ICP curves that can be used to monitor the charging effect in the test device structure.

In order to produce the ICP curve, bias voltages can be applied to diffusion regions 104 and 118, substrate 102, and the gate structure. As illustrated in FIG. 3A, a 0V bias voltage can be applied to both diffusion regions 104 and 108, as well as substrate 102. Bias voltage pulses can then be applied to the gate structure. FIG. 3B is a diagram illustrating example bias voltage pulses that can be applied to the gate structure. As can be seen, the pulses have a period (t) and therefore a frequency equal to 1/t. Electron Charge will be trapped in the interface between layers 102 and 124 when the gate pulse level is higher than the inversion level as illustrated in FIG. 3B. Electron Charge will be released when the gate bias pulses pulse level is lower than the inversion level. The released electron charge can be measured at drain 104 and/or source 118. The measured electron charge is the ICP current.

FIG. 3C is a diagram illustrating an example ICP current curve 126. As can be seen, at the inversion boundary ICP current curve 126 transitions from a low to a high. The high can be referred to as the ICP max, which can be defined using the following equation:
ICP max=q*Nit*f*A,

where f=frequency and
A=area.

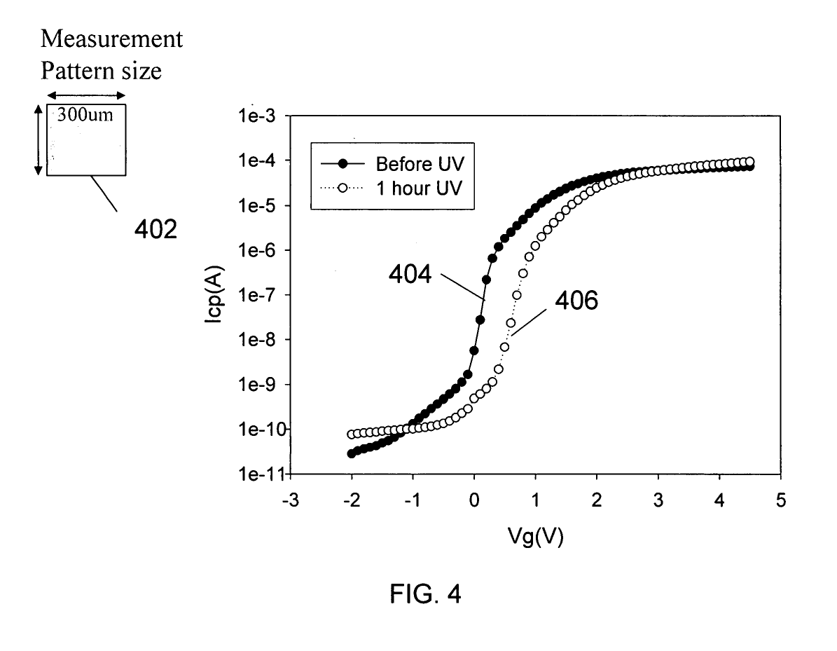

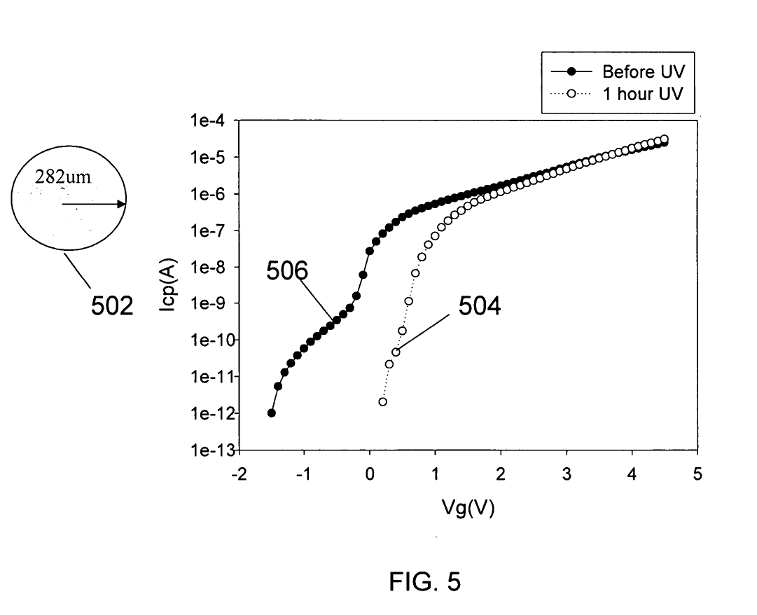

By monitoring changes in the ICP curve, the charging effect can be detected and measured. This can be illustrated in FIGS. 4 and 5. FIG. 4 is a diagram illustrating the ICP curve for a 300 μm² test device pattern 402. The curve of FIG. 4 illustrates an ICP curve 404 before UV exposure and an ICP current curve 406 produced after one hour of UV exposure. As can be seen, the ICP curve shifts to the right after one hour of UV exposure. This shift can be used to detect the charging effect.

FIG. 5 illustrates the ICP curve for an elliptical test device structure 502 comprising a radius of 202 μm. ICP curve 506 is representative of the ICP current before UV exposure, while ICP curve 504 is representative of the ICP current after one hour of UV exposure. Again, it can be seen that the ICP curve shifts to the right. This shift can be used to detect the charge in effect.

As mentioned above, and as illustrated in FIGS. 4 and 5, different test device structures comprising different parameters, areas, and test patterns or shapes can be used in accordance with the methods described herein. FIGS. 4 and 5 illustrate two examples of test device patterns that can be used in accordance with the methods described herein; however, it will be clear that many different test device patterns can be used. Co-pending U.S. patent application Ser. No. TBD entitled “A Test Structure And Method For Detecting Charge Effects During Semiconductor Processing,” filed on TBD, which is incorporated herein in its entirety as it is set forth and full, describes further example test structures and patterns that can be used in accordance with the methods described herein. Again, these test patterns are by way of example only and should not be seen as limiting the apparatus or methods described herein to any particular test device structure or pattern.

Thus, the embodiments described above provides for a simple test structure that can be used to monitor the charging effect by monitoring the shift in the ICP curve. The embodiments described above provide a non-destructive and re-testable measurement method that can detect both plasma and UV charging effect.

While certain embodiments of the inventions have been described above, it will be understood that the embodiments described are by way of example only. Accordingly, the inventions should not be limited based on the described embodiments. Rather, the scope of the inventions described herein should only be limited in light of the claims that follow when taken in conjunction with the above description and accompanying drawings.

What is claimed:

1. A method for determining a charge status, comprising:
forming a test structure on a silicon substrate, the test structure, comprising:
a substrate;
a diffusion region formed in the substrate,
a gate electrode above the substrate and diffusion region, and
a charge trapping layer between the gate electrode and the substrate and diffusion region, the charge trapping layer configured to accumulate charge imparted during the semiconductor processing step;
performing a semiconductor processing step; and
measuring a charge pumping current for the test structure before and after the semiconductor processing step.

2. The method of claim 1, wherein the diffusion region and the gate electrode are metallized.

3. The method of claim 1, wherein the test structure comprises at least one diffusion region.

4. The method of claim 1, further comprising an isolation region.

5. The method structure of claim 1, further comprising a spacer layer on the sidewall of the gate electrode.

6. The method of claim 3, wherein the charge pumping current is produced by applying bias voltages to the drain diffusion region, source diffusion region, substrate, and gate electrode.

7. The method of claim 6, wherein the bias voltage applied to the drain diffusion region, source diffusion region, and substrate is 0V.

8. The method of claim 6, wherein the bias voltage pulses are applied to the gate structure.

9. The method of claim 8, wherein charge is trapped in the interface layer between substrate and bottom oxide when the bias voltage pulse applied to the gate is higher than an inversion level.

10. The method of claim 8, wherein charge is released from the interface layer between substrate and bottom oxide when the bias voltage pulse applied to the gate is lower than the inversion level.

11. The method of claim 1, further comprising measuring a shift in the charge pump current after the processing step relative to the charge pumping current before the processing step.

12. The method of claim 11, wherein the charge status is determined based on the shift in the charge pumping current.

13. The method of claim 1, wherein the charge trapping layer is a nitride layer, Al2O3, Hf2O3, other metal oxide and other charge storage material.

14. The method of claim 1, wherein the charge trapping layer comprises a nitride layer sandwiched between two oxide layers.

15. A test structure for monitoring a semiconductor processing step comprising:
a substrate;
a diffusion region formed in the substrate;
a gate electrode above the substrate and diffusion region; and
a charge trapping layer between the gate electrode and the substrate and diffusion region, the charge trapping layer configured to accumulate charge imparted during the semiconductor processing step.

16. The test structure of claim 15, wherein the diffusion region and the gate electrode are metallized.

17. The test structure of claim 15, wherein the test structure comprises at least one diffusion region.

18. The test structure of claim 15, further comprising an isolation region.

19. The test structure of claim 15, further comprising a spacer layer on the sidewall of the gate electrode.

20. The test structure of claim 15, wherein the charge trapping layer is a nitride layer, Al2O3, Hf2O3, other metal oxide and other charge storage material.

21. The test structure method of claim 15, wherein the charge trapping layer comprises a nitride layer sandwiched between two oxide layers.
